(19) United States
(12) Patent Application Publication
(10) Pub. No.: US 2018/0323069 A1
(43) Pub. Date: Nov. 8, 2018

(54) METHOD AND DEVICE FOR ALIGNING A FIRST SUBSTRATE WITH A SECOND SUBSTRATE

(71) Applicant: SUSS MicroTec Lithography GmbH, Garching (DE)

(72) Inventor: Katrin Schindler, Garching (DE)

(21) Appl. No.: 15/970,303

(22) Filed: May 3, 2018

(30) Foreign Application Priority Data
May 5, 2017 (NL) 2018856

(51) Int. Cl. H01L 21/20; H01L 21/18; H01L 23/544; H01L 33/00; C09J 9/02

(52) U.S. Cl. CPC H01L 21/2007; H01L 21/187; C09J 9/02; H01L 33/0079; H01L 23/544

(57) ABSTRACT

A method for aligning a first substrate, in particular a mask, with a second substrate, in particular a wafer, comprises inserting the first substrate and the second substrate into a positioning means; capturing at least one joint image of the first substrate and the second substrate; displaying the image; a plurality of image points in the image being marked by a user; and determining a control command for actuating the positioning means on the basis of the marked image points in such a way that the substrates are aligned with one another.

### CROSS-REFERENCE TO RELATED APPLICATIONS AND PRIORITY

This patent application claims priority from Dutch Patent Application No. 2018856 filed on May 5, 2017, the entirety of which is hereby incorporated by reference.

The present invention relates to the field of aligning substrates, in particular in a mask aligner or bond aligner.

### BACKGROUND OF THE INVENTION

In semiconductor technology, it is known to align two substrates arranged one above the other. For example, in mask aligners, a photomask and a wafer are precisely aligned with one another before the wafer is illuminated through the photomask. Likewise, in bond aligners two wafers are initially aligned with one another before they are subsequently permanently or temporarily bonded. This alignment is carried out either manually by a user or automatically.

In manual alignment, the user controls the movement of at least one of the substrates, generally directly by means of a joystick. This direct control requires an exact understanding on the part of the user as to what change in position of a substrate relative to the other substrate is brought about by an input using the joystick. Manual alignment therefore initially has to be learnt by the user, and this can lead to considerable expenditure of time and money.

In automatic alignment (auto-alignment), an offset and a skew of the substrates with respect to one another are automatically detected, for example by detecting matching adjustment marks on the substrate surfaces using image recognition software. The wafers are subsequently aligned fully automatically, without a user input being required. However, this type of alignment is complex, since the image recognition software initially has to be trained to recognise the adjustment marks (target training).

Further, only substrates having suitable adjustment marks can be aligned by auto-alignment. The adjustment marks must not be confusable or damaged and have to be recognisable even when overlapping in part. Automatic alignment of individual substrates having different types of adjustment marks is therefore often not possible.

Therefore, the object of the present invention is efficiently to align two substrates, in particular a mask and a wafer, with one another. In particular, this alignment should be simple for a user and be implementable without specialist knowledge.

### BRIEF DESCRIPTION OF THE INVENTION

This object is achieved by the features of the independent claims. Advantageous developments form the subject matter of the dependent claims, the description and the drawings.

A first aspect of the invention relates to a method for aligning a first substrate, in particular a mask, with a second substrate, in particular a wafer, comprising: inserting the first substrate and the second substrate into a positioning means; capturing at least one joint image of the first substrate and the second substrate; displaying the image; a plurality of image points in the image being marked by the user; and determining a control command for actuating the positioning means on the basis of the marked image points, in such a way that the substrates are aligned with one another. This achieves the advantage that the two substrates can be aligned with one another in a very simple manner. In particular, in this context there is no direct control of the positioning means, which is often very complicated, by the user, for example by means of a joystick, simplifying the implementation of the method for the user. It is also not necessary to train image recognition software for particular adjustment marks first.

By the method, the substrates can be aligned with one another before subsequently being joined and/or illuminated, for example in a lithography or bonding process.

The substrates may each be a wafer. Further, the first substrate may be a mask, in particular a lithography mask or photomask, and the second substrate may be a wafer. The substrates may comprise structures, in particular adjustment marks, alignment targets or alignment aids, for aligning the substrates.

The substrates may each be formed from a semiconductor material, for example silicon (Si) or gallium arsenide (GaAs), a glass, for example quartz glass, a plastics material or a ceramic. The first substrate and/or the second substrate may each be formed from a monocrystalline, a polycrystalline or an amorphous material. Further, the substrates may each comprise a plurality of bonded materials.

The substrates may comprise electrical circuits, for example transistors, LEDs or photodetectors, electrical conductor paths which connect these circuits, or optical components, as well as MEMS or MOEMS structures. The first substrate and/or the second substrate may further comprise coatings, for example structured chromium layers, pre-cross-linked or cured bonding adhesives, or separating layers.

The at least one joint image of the substrates may show surface portions of the first substrate and of the second substrate, which are in particular arranged one above the other. In the surface portions, adjustment marks and/or device structures may be visible which can be used for aligning the substrates.

A surface position on the first substrate or second substrate may be assigned to each marked image point. Aligning the substrates with one another may comprise arranging the substrates one on top of the other, specifically in such a way that the marked surface positions of the substrates are aligned with one another. For example, the user marks an adjustment mark of the first substrate and an adjustment mark of the second substrate in the image in succession, and the positioning means subsequently aligns the marked adjustment marks with one another.

If a plurality of joint images are captured and displayed, each of these images may show matching adjustment marks of the substrates. The user can mark the adjustment marks in each image in succession, in such a way that all matching adjustment marks are aligned with one another. Further, by way of the marked adjustment marks, an average of the offset of the substrates, on the basis of which the substrates are aligned with one another, can be calculated using an algorithm.

In one embodiment, the substrates are aligned with one another laterally in response to the positioning means receiving a control command. This makes it possible to align the substrates simply and rapidly without the user controlling the positioning means directly.

In one embodiment, before the control command is determined, a machine state is detected, for example a current process step, a machine type or a machine configuration.

In one embodiment, the control command is additionally determined on the basis of the detected machine state. This achieves the advantage that the substrates can be aligned efficiently whilst taking into account the machine state. For example, it is determined in this context which axes can and/or which axes cannot be displaced in the current machine state.

In one embodiment, the plurality of image points are marked in the image by the user by clicking on the image points, for example using a peripheral device, or by dragging a mouse cursor. This achieves the advantage that the image points can be marked in a particularly simple manner.

In one embodiment, the plurality of image points are marked in the image by the user by touching a touch display. This achieves the advantage that the image points can be marked in a particularly simple and intuitive manner. The marking can be carried out by selectively touching the image points on the touch display or by way of a swiping movement over the touch display.

In one embodiment, the method step of capturing the image comprises capturing a first joint image and a second joint image of the substrates, the first and the second joint image being displayed side by side, one above the other or alternately. This achieves the advantage that the substrates can be aligned with one another particularly efficiently on the basis of two images. In particular, a skew or angular offset of the substrates with respect to one another can be corrected. Further, the orientation can be particularly simple and intuitive for the user to implement.

In one embodiment, at least two image points in the first joint image and at least two image points in the second joint image are marked. This achieves the advantage that the substrates can be aligned with one another particularly efficiently on the basis of the two images. At each marked image point, there may be an adjustment mark of the first or second substrate in the first or second image.

A second aspect of the invention relates to a device for aligning a first substrate with a second substrate, comprising a positioning means into which the substrates can be inserted; an image capture means which is configured to capture at least one joint image of the substrates inserted into the positioning means; an input device by means of which a plurality of image points can be marked in the image; and a control element which is configured to determine a control command for actuating the positioning means on the basis of the marked image points. This achieves the advantage that the two substrates can be aligned with one another in a very simple and efficient manner without the user or an image recognition software having to be trained.

The device may be integrated into a production system for microstructure components, for example a mask aligner or a bond aligner.

The positioning means may be formed to align the substrates with one another, in particular laterally with respect to one another, in response to receiving the control command.

In one embodiment, the device comprises a display device, in particular a screen or a display, for displaying the image. This achieves the advantage that the image can be displayed to the user in such a way that he can mark the image points in the display device.

In one embodiment, the display device and the input device form a touch display. This achieves the advantage that the user can mark the image points in a particularly simple manner by touching the touch display, for example with a finger or an input pen or stylus.

In one embodiment, the input device is a peripheral device, for example a mouse, a trackball or a touchpad. This achieves the advantage that the user can mark the image points in a particularly simple manner by operating the input device.

In one embodiment, the positioning means comprises a substrate positioning device for the first substrate and/or a substrate positioning device for the second substrate. This achieves the advantage that the substrates can be precisely positioned with respect to one another. In this context, the substrate positioning devices may each make it possible for the substrates to move with one or more degrees of freedom of movement.

In one embodiment, the image capture means comprises at least one microscope. This makes possible particularly exact marking of image points by the user. For example, in an enlarged display of the substrates the user can mark centres or corners of adjustment marks more exactly, in such a way that they are aligned more exactly with one another.

In one embodiment, the image capture means comprises a number of image cameras, which are arranged above and/or below and/or inside the positioning means. This achieves the advantage that the joint images can be captured efficiently.

In one embodiment, the image capture means comprises a movement means for positioning the number of image cameras, the movement means being controllable by means of the input device. This makes it possible to align the image capture device exactly with the substrates. In this way, structures such as adjustment marks on the substrate surfaces can be approached selectively with the image capture means.

Further, an enlargement setting of the image capture means may be settable by means of the input device. The user for example initially displaces the image capture means until adjustment marks or other relevant structures are visible. Subsequently, the user can enlarge the display of the substrates in the image capture so as to make it possible to mark the adjustment marks or the structures as exactly as possible.

### BRIEF DESCRIPTION OF THE DRAWINGS

Further embodiments are described in greater detail with reference to the accompanying drawings, in which:

FIG. 1 is a flow chart of a method for aligning a first substrate with a second substrate;

FIG. 2 is a schematic drawing of a device for aligning a first substrate with a second substrate;

FIG. 3a-d are schematic drawings of a joint image of two substrates during alignment of the substrates; and

FIG. 4a-b are schematic drawings of a first joint image and a second joint image of two substrates during alignment of the substrates.

### DETAILED DESCRIPTION OF THE INVENTION

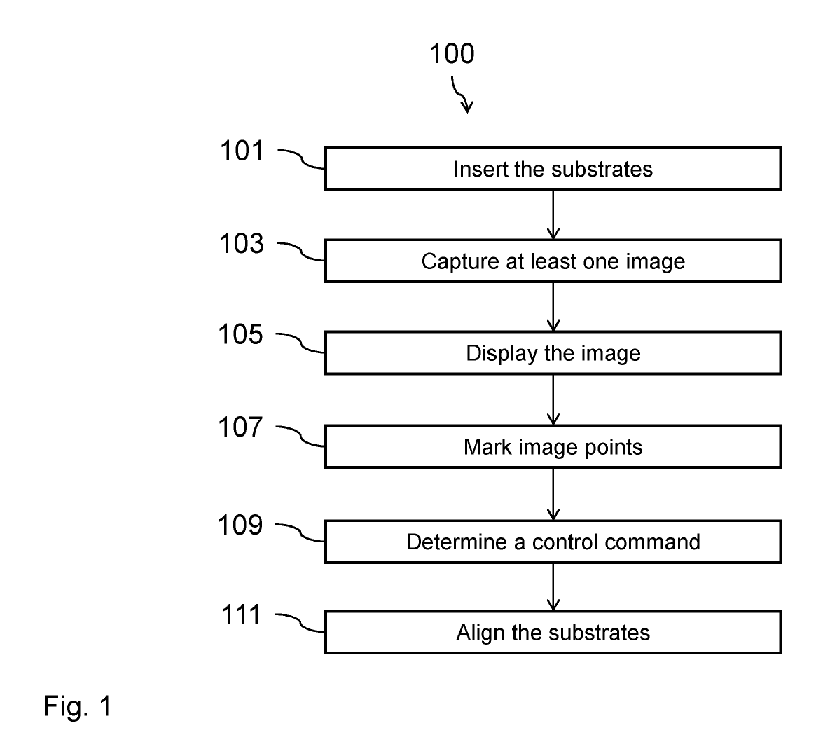

FIG. 1 is a flow chart of a method 100 for aligning a first substrate with a second substrate in accordance with an embodiment.

The method 100 comprises inserting 101 the first substrate and the second substrate into a positioning means, capturing 103 at least one joint image of the first substrate and the second substrate, displaying 105 the image, a plurality of image points in the image being marked 107 by the user, and determining 109 a control command for actuating the positioning means on the basis of the marked image points, in such a way that the substrates are aligned with one another.

The alignment 111 is carried out by the positioning means in response to receiving the control command.

Aligning 111 the substrates with one another may comprise laterally aligning the substrates. Aligning 111 the substrates with one another may further comprise arranging the substrates one above the other, specifically in such a way that surface portions of the substrates corresponding to the marked image points are aligned with one another.

The first substrate may be a mask and the second substrate may be a wafer, in particular a semiconductor wafer. Further, both substrates may be wafers, in particular semiconductor wafers or glass wafers. The substrates may comprise structures, in particular adjustment marks, alignment targets or alignment aids, for assisting with the alignment.

By the method 100, the substrates can be aligned with one another before subsequently being joined and/or illuminated, for example in a lithography or bonding process.

Before the method step of determining 109 the control command, a machine state may be detected. The machine state is for example a current process step, a machine type or a machine configuration. The detected machine state may comprise information regarding the type or current configuration of the positioning means and/or of an image capture means, or regarding an enlargement setting for the image capture. The detected machine state can be taken into account when determining 109 the control command.

The image points can be marked 107 by clicking on the image points using a peripheral device or by touching a touch display. In this context, the user for example marks at least two image points in each of the captured joint images. The first marked image point may correspond to a surface position on the first substrate and the second marked image point may correspond to a surface position on the second substrate. In this context, the user can orientate himself using structures on the substrate surfaces, such as adjustment marks or noniuses.

The user can further carry out the marking 107 by dragging a mouse cursor or by swiping over the touch display. In this context, for example a start point of the dragging or swiping movement marks the surface position on the first substrate and an end point of the dragging or swiping movement marks the surface position on the second substrate with which the surface position on the first substrate is to be aligned.

The marked image points may be graphically distinguished in the shared image, for example using a coloured marking of the image points, a symbol displayed at the image points, or an arrow from the first marked image point to the second marked image point.

The substrates may be aligned in such a way that the respective surface positions corresponding to the marked image points are arranged above one another.

After the method 100 is completed, an enlargement setting of the at least one joint image can be increased and the method 100 can be carried out afresh. In this way, the most precise possible alignment of the substrates with one another can be achieved.

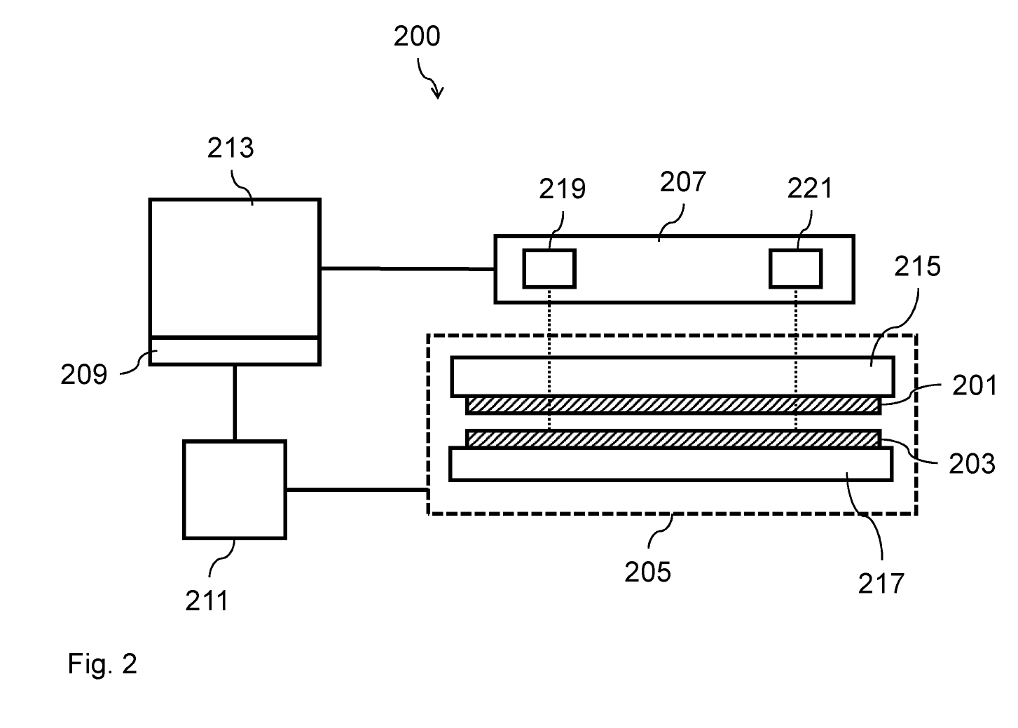

FIG. 2 shows a device 200 for aligning the first substrate 201 with the second substrate 203 in accordance with an embodiment.

The device 200 comprises a positioning means 205 into which the substrates 201, 203 can be inserted; an image capture means 207 which is configured to capture at least one joint image of the substrates 201, 203 inserted into the positioning means 205; an input device 209 by means of which a plurality of image points can be marked in the image; and a control element 211 which is configured to determine a control command for actuating the positioning means 205 on the basis of the marked image points.

The device 200 may be integrated into a production system for microstructure components, for example a mask aligner or a bond aligner.

The substrates 201, 203 may each be a wafer. Further, the first substrate 201 may be a mask, in particular a lithography mask or photomask, and the second substrate 203 may be a wafer. The substrates 201, 203 may comprise structures, in particular adjustment marks, alignment targets or alignment aids, for aligning the substrates.

The substrates 201, 203 may each be formed from a semiconductor material, for example silicon (Si) or gallium arsenide (GaAs), a glass, for example quartz glass, a plastics material or a ceramic. The first substrate 201 and/or the second substrate 203 may each be formed from a monocrystalline, a polycrystalline or an amorphous material. Further, the substrates 201, 203 may each comprise a plurality of bonded materials.

The substrates 201, 203 may comprise electrical circuits, for example transistors, LEDs or photodetectors, electrical conductor paths which connect these circuits, or optical components, as well as MEMS or MOEMS structures. The first substrate 201 and/or the second substrate 203 may further comprise coatings, for example structured chromium layers, pre-cross-linked or cured bonding adhesives, or separating layers.

The device 200 may comprises a display device 213, for example a screen or a display, for displaying the image.

The display device 213 and the input device 209 may form a touch display. The image points can be marked by touching the touch display. The input device 209 may further comprise a peripheral device, such as a mouse, a trackball, a touchpad or a keyboard.

The control element 211 may comprise a processor unit for determining the control command. The control element 211 and the positioning means 205 may be communicatively interconnected.

In one embodiment, the display device 213, the input device 209 and/or the control element 211 are integrated into a data processing system, for example a computer, a laptop, a tablet or a smartphone. The data processing system may be communicatively connected to the positioning means 205 and the image capture means 207. The data processing system may be an external device, in particular an external device carriable by the user.

The positioning means 205 may comprise a substrate positioning device 215 for the first substrate 201 and a substrate positioning device 217 for the second substrate 203. The substrate positioning devices 215, 217 may be formed to move the first substrate 201 and/or the second substrate 203, and may in this context each have one or more degrees of freedom. The substrate positioning devices 215, 217 may each comprise supports and/or mountings for the substrates 201, 203.

The substrate positioning devices 215, 217 may comprise stages. The substrate positioning devices 215, 217 may each be formed for translation along up to three linear axes and/or rotation about up to three axes of rotation. For example, the substrate positioning devices 215, 217 each comprise xy-stages having an additional axis of rotation in the z-direction.

The substrate positioning device 215 for the first substrate 201 may comprise a mask mounting or mask chuck. The substrate positioning device 217 for the second substrate 203 may comprise a chuck, in particular a wafer chuck.

The example image capture means 207 in FIG. 2 further comprises two image cameras 219, 221 which are arranged above the positioning device 205 and aligned towards the substrates 201, 203 for image capture. The upper substrate positioning device 215 in FIG. 2 may be transparent to light, and the first substrate 201 may be at least partially transparent. Thus, in the configuration shown in FIG. 2 the image cameras 219, 221 can capture joint image captures of the substrates 201, 203 arranged one above the other.

In an embodiment, additional image cameras are arranged below the positioning means 205. In a configuration of this type, the upper image cameras 219, 221 and the lower image cameras can each capture image captures of the mutually remote faces of the substrates 201, 203. These image captures may be superposed to generate the shared image. In this way, alignment of the substrates on the basis of structures on the mutually remote faces of the substrates (BSA, back side alignment) can be made possible.

In a further embodiment, an image capture means 207 or the image cameras 219, 221 may also be arranged between the substrates so as to make inter-substrate alignment (ISA) possible.

In one embodiment, the image capture means 207 comprises a movement means for positioning the number of image cameras 219, 221.

The movement means may be controllable by the user by means of the input device 209. The user can thus selectively approach particular surface regions, for example to ensure that adjustment marks of both substrates are visible in each shared image capture.

In a further embodiment, the image capture means 207 comprises at least one microscope. For example, each image camera 219, 221 may comprise a microscope. Using the microscope, the substrates can be represented enlarged in the joint image, and particularly exact marking of image points can thus be made possible. For example, the user can mark the centre or another feature of the adjustment marks very precisely in an enlarged representation, in such a way that they can be aligned with one another very exactly.

In a further embodiment, the image cameras 219, 221 are digital cameras having an enlargement or zoom function.

In a further embodiment, an enlargement setting of the image capture means 207 is settable by means of the input device 209. The user for example initially displaces the image capture means 207 until adjustment marks are visible in every image capture. Subsequently, the user enlarges the representation of the adjustment marks in the image capture so as to make possible the most exact marking possible of the adjustment marks.

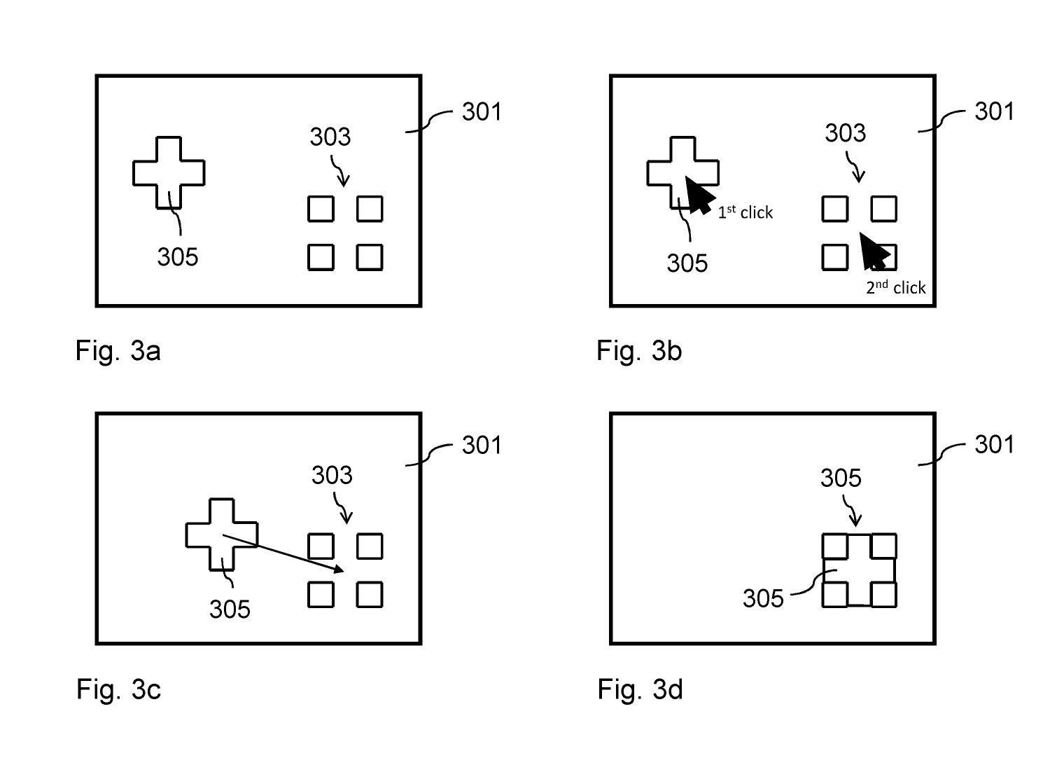

FIG. 3a-d are schematic drawings of a joint image 301 of two substrates 201, 203 during alignment of the substrates 201, 203 in accordance with an embodiment.

The image shown in FIG. 3a-d can be displayed by the display device 213 during the alignment process.

The shared image 301 in FIG. 3a-d shows an adjustment mark 303 of the first substrate and a matching adjustment mark 305 of the second substrate 203 in each case. For example, the adjustment mark 303 is a wafer target and the adjustment mark 305 is a mask target.

In FIG. 3a, the adjustment marks 303, 305 are offset, since the substrates 201, 203 are not yet aligned with one another. “offset” means that the adjustment marks 303, 305 are laterally offset from one another, and not one above the other, as considered perpendicular to a plane parallel to the substrates. For further processing, however, the substrates are to be aligned with one another. For this purpose, a user can guide the wafer target 305 exactly below the mask target 303. For this purpose, he can mark the respective positions of the targets 303, 305 using the input device.

FIG. 3b shows this marking of the adjustment marks 303, 305 by the user. In this context, the user clicks in the centre of the adjustment mark 303 of the first substrate 201 and subsequently in the centre of the adjustment mark 305 of the second substrate 203 using a mouse cursor.

It may also be provided that the control system assigns a click on an adjustment mark to the closest mark even if said mark is not “hit” exactly.

The control element 211 can calculate an offset (displacement) of the substrates 201, 203 on the basis of the marked image points. In this context, a machine type, for example manual or automatic, and an alignment mode, for example TSA, BSA or ISA, may be taken into account. The offset can be calculated as a displacement in the x- or y-direction, as a translation and/or as a skew. The control element 211 may determine a control command for actuating the positioning means 205 on the basis of the determined offset.

FIG. 3c shows alignment of the substrates with one another. In the example in FIG. 3c, only the second substrate 203 is moved, in such a way that the adjustment mark 305 of the second substrate 203, for example the wafer, moves towards the adjustment mark 303 of the first substrate 201, for example the mask. The marked image points which are aligned with one another are shown as two points connected by an arrow.

FIG. 3d shows the adjustment marks 303, 305 positioned above one another after successful alignment of the substrates 201, 203.

For changing the alignment of the substrates 201, 203, the user may also mark any other desired image points in the joint image 301, instead of the centres of adjustment marks as shown in FIG. 3a-d. The surface positions of the substrates 201, 203 which correspond to these marked image points are subsequently aligned with one another.

Subsequently, the process shown in FIG. 3a-d can be repeated, for example using increased enlargement, so as to carry out fine alignment of the substrates 201, 203.

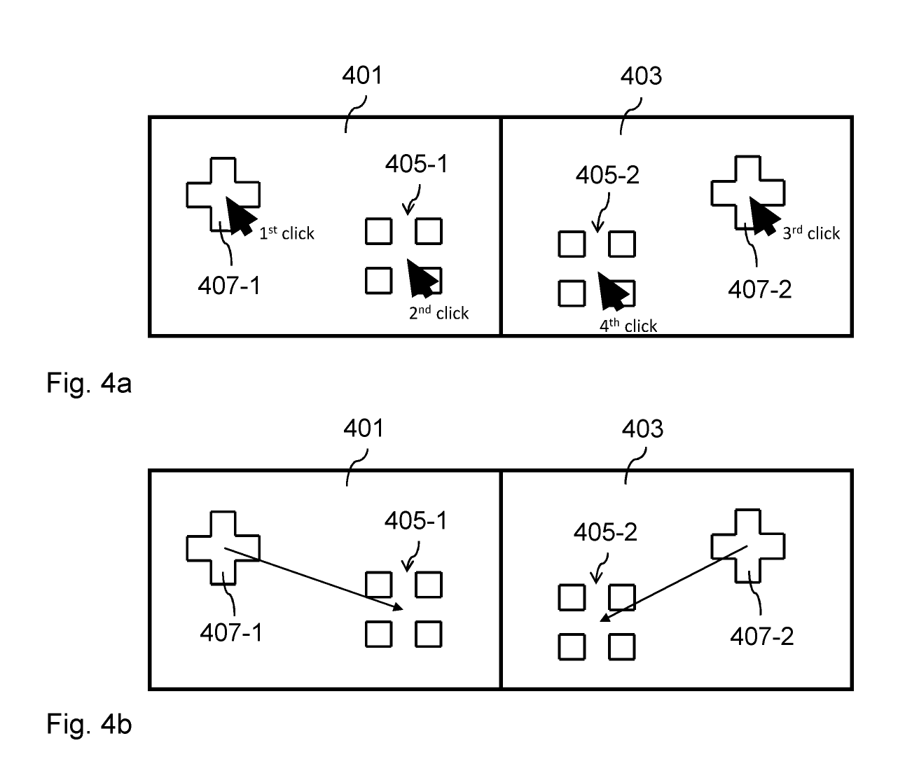

FIG. 4a-b are schematic drawings of a first joint image 401 and a second joint image 403 of two substrates 201, 203 during alignment of the substrates 201, 203 in accordance with a further embodiment.

The two images 401, 403 each show different surface portions arranged above one another of the substrates 201, 203. For example, each of the images 401, 403 is captured by one of the image cameras 219, 221 of the image capture means 207 of FIG. 2. Alternatively, both images could be captured by just one image camera, which travels along different surface portions of the substrates 201, 203 (single TSA). In both images 401, 403, adjustment marks 405-1, 405-2 of the first substrate and adjustment marks 407-1, 407-2 of the second substrate 203 are visible.

The display device 213 may be formed to display the two images 401, 403 side by side. Alternatively, the images 401, 403 may also be displayed in succession or alternately, in which case the user can select which the images 401, 403 is actually shown to him.

FIG. 4a shows marking of the respectively matching adjustment marks 405-1, 407-1, 405-2, 405-2 in the two images 401, 403. In this context, the user clicks for example in succession in the centre of the adjustment marks 405-1, 407-1 in the first image 401 and subsequently in the centre of the adjustment marks 405-2, 407-2 in the second image 403 using a mouse cursor.

In an optional process step, before marking the matching adjustment marks 405-1, 407-1, 405-2, 405-2, the user can initially only mark the adjustment marks 405-1, 405-2, of one of the substrates 201, 203, whereupon they are each passed into the centre of the shared images 401, 403 by moving the image camera 219, 221. Subsequently, the respectively matching adjustment marks 405-1, 407-1, 405-2, 405-2 can be marked, as shown in FIG. 4a.

FIG. 4b shows the subsequent alignment of the substrates with one another. In this context, the substrates are aligned with one another in such a way that the matching adjustment marks 405-1, 407-1 and 405-2, 407-2 are arranged above one another. In this context, the alignment takes place in that the substrates 201, 203 are moved by the positioning means 205.

As an alternative to the simultaneous alignment shown in FIG. 4b of the adjustment marks 405-1, 407-1 in the first image 401 and the adjustment marks 405-2, 407-2 in the second image 403, it is possible for only the adjustment marks 405-1, 407-1 in the first image 401 to be marked and aligned with one another initially in a first step, and for the adjustment marks 405-2, 407-2 in the second image 403 to be marked and aligned with one another in a subsequent second step. In this context, the control element 211 can actuate the positioning means 207 in such a way that the alignment of the initially aligned adjustment marks 405-1, 407-1 is maintained during the displacement and alignment of the further adjustment marks 405-2, 407-2.

Alignment of substrates by the method shown in FIG. 3a-d and FIG. 4a-b is much simpler and more intuitive for the user than directly controlling a positioning means as is usual for example in conventional manual mask aligners. For direct control using a control device such as a joystick, the user directly controls the rotation and the x- and y-translation of the substrates. This presumes that the user knows the exact mode of operation of the positioning means in question and can evaluate in what direction a rotation of substrates will move the individual adjustment marks. When the substrates 201, 203 are aligned by marking image points, knowledge of this type is not required.

Further, no target training, as with automatic alignment (auto-alignment), is required for the alignment. The positions of the substrates which are to be arranged above one another are selected by the user, making it possible to reduce the complexity of the device 200.

In addition, no auto-alignment of appropriate adjustment marks is required for carrying out the method 100. Any suitable structures, for example including noniuses or long lines along the substrate surface, may be used for aligning the substrates. Since the user marks the structures himself, they may be formed differently in each substrate.

Further, the method 100 is also additionally usable in systems formed for automatic alignment (auto-alignment). For example, in case of error the user can correct the alignment of substrates manually, or for special substrates having unsuitable adjustment marks, for example during process development, he can carry out the alignment himself.

### LIST OF REFERENCE NUMERALS

100 Method
101 Inserting
103 Capturing
105 Displaying
107 Marking
109 Determining
111 Aligning
200 Device
201 First substrate
203 Second substrate
205 Positioning means
207 Image capture means
209 Input device
211 Control element
213 Display device
215 Substrate positioning device
217 Substrate positioning device
219 Image camera
221 Image camera
301 Image
303 Adjustment mark of the first substrate
305 Adjustment mark of the second substrate
401 First image
403 Second image
405-1 Adjustment mark of the first substrate
405-2 Adjustment mark of the first substrate
407-1 Adjustment mark of the second substrate
407-2 Adjustment mark of the second substrate

1. A method for aligning a first substrate, in particular a mask, with a second substrate, in particular a wafer, comprising:
inserting the first substrate and the second substrate into a positioning means;
capturing at least one joint image of the first substrate and the second substrate;
displaying the image;
a plurality of image points in the image being marked by a user; and
determining a control command for actuating the positioning means on the basis of the marked image points, in such a way that the substrates are aligned with one another.

2. The method of claim 1 wherein the substrates are aligned with one another laterally in response to the positioning means receiving a control command.

3. The method according of claim 1 wherein, before the control command is determined, a machine state is detected, for example a current process step, a machine type or a machine configuration.

4. The method of claim 3 wherein the control command is additionally determined on the basis of the detected machine state.

5. The method of claim 1 wherein the plurality of image points are marked in the image by the user by clicking on the image points, for example using a peripheral device, or by dragging a mouse cursor.

6. The method of claim 1 wherein the plurality of image points are marked in the image by the user by touching a touch display.

7. The method of claim 1 wherein the method step of capturing the image comprises capturing a first joint image and a second joint image of the substrates, the first and the second joint image being displayed side by side, one above the other or alternately.

8. The method of claim 7 wherein at least two image points in the first joint image and at least two image points in the second joint image are marked.

9. A device for aligning a first substrate with a second substrate, comprising
a positioning means into which the substrates can be inserted;
an image capture means which is configured to capture at least one joint image of the substrates inserted into the positioning means;
an input device by means of which a plurality of image points can be marked in the image; and
a control element which is configured to determine a control command for actuating the positioning means on the basis of the marked image points.

10. The device of claim 9 wherein the device comprises a display device, in particular a screen or a display, for displaying the image.

11. The device of claim 9 wherein the display device and the input device form a touch display.

12. The device of claim 9 wherein the input device is a peripheral device, for example a mouse, a trackball or a touchpad.

13. The device of claim 9 wherein the positioning means comprises a substrate positioning device for the first substrate and/or a substrate positioning device for the second substrate.

14. The device of claim 9 wherein the image capture means comprises at least one microscope.

15. The device of claim 9 wherein the image capture means comprises a number of image cameras, which are arranged above and/or below and/or inside the positioning means.

16. The device of claim 9 wherein the image capture means comprises a movement means for positioning the number of image cameras, the movement means being controllable by means of the input device.
